(19) United States
(12) Patent Application Publication
(10) Pub. No.: US 2026/0353584 A1
(43) Pub. Date: Nov. 5, 2026

(54) CONTROL DEVICE, DRIVE UNIT HAVING A CONTROL DEVICE, AND METHOD FOR PRODUCING A DRIVE UNIT

(71) Applicant: Robert Bosch GmbH, Stuttgart (DE)

(72) Inventors: Baskaran Asween Raaj, Gobichettipalayam, Tamil Nadu (IN); Stephan Leonhardt, Bretten (DE); Thangavelan Prabhu, Bangalore (IN); Vincenzo De Renzi, Ludwigsburg (DE)

(21) Appl. No.: 19/105,065

(22) PCT Filed: Nov. 3, 2023
(86) PCT No.: PCT/EP2023/080712

§ 371 Date: Feb. 20, 2025

(30) Foreign Application Priority Data
Nov. 4, 2022 (DE) 10 2022 211 669.0

(51) Int. Cl. H05K 7/14; H01R 12/70; H02K 5/22; H02K 11/33

(52) U.S. Cl. CPC H05K 7/1432; H01R 12/7052; H01R 12/707; H02K 5/225; H02K 11/33; H02K 2211/03

(57) ABSTRACT

A control device for controlling an electric motor. The control device has a housing which has an interior and in which a circuit carrier which includes an electronic circuit is arranged in the form of a printed circuit board; and first contact elements, which are electrically conductively connected to the electronic circuit, wherein the first contact elements are designed to be welded to second contact elements of the electric motor, wherein the printed circuit board has through-openings for guiding through the second contact elements and for bringing the second contact elements into overlap with the first contact elements in respective welding portions, wherein at least one guide element for aligning the second contact elements with the through-openings and the welding portions is arranged in the interior of the housing on the side of the printed circuit board that is opposite to the first contact elements.

### FIELD

The present invention relates to a control device for controlling an electric motor, which control device is characterized by particularly advantageous or economical manufacturing. Furthermore, the present invention relates to a drive unit consisting of a control device designed according to the present invention and an electric motor connected to the control device. The present invention also comprises a method for producing such a drive unit.

### BACKGROUND INFORMATION

Germany Patent Application No. DE 10 2019 217 862 A1 describes a control device whose plug for electrically contacting the control device with a mating plug comprises a plurality of plug pins designed as punched/bent parts. In order to connect the plug pins or contact elements in an electrically conductive manner to an electronic circuit on a printed circuit board, a plate-shaped guide element with through-openings is fastened to a plug body of the plug and positions the plug pins to one another and aligns them flush with through-openings formed in the printed circuit board, in order to make it possible to connect the plug pins easily to the printed circuit board.

Furthermore, European Patent No. EP 3 167 539 B1 describes arranging a welding protection element in an electromechanical actuating drive in the region of contact elements to be welded together, in order to avoid weld spatters or the like, the welding protection element preventing components on a circuit carrier from being damaged or pre-damaged where necessary.

### SUMMARY

A control device according to the present invention for controlling an electric motor may have the advantage that a particularly safe and reliable assembly of contact elements of an electric motor with cooperating contacts in the control device takes place, wherein the mentioned contact elements of the electric motor and of the control device are welded together. In particular, the control device according to the present invention makes it possible for the control device to be connected to the contact elements of the electric motor in a state in which the control device is substantially already completely manufactured.

The present invention is based on the idea of equipping the control device on the one hand with at least one guide element for the motor-side contact elements in such a way that, when connecting contact elements of the electric motor and guiding these contact elements through the interior of the control device, the motor-side contact elements precisely pass through through-openings in a printed circuit board of the control device, and of using a welding protection element on the other hand to protect the interior of the control device, in particular an electronic circuit on a printed circuit board, in a subsequent welding process, when connecting the contact elements of the control device to the contact elements of the electric motor.

According to an example embodiment, it is provided in a control device according to the present invention for controlling an electric motor that the control device comprises a housing which has an interior and in which a circuit carrier which comprises an electronic circuit is arranged in the form of a printed circuit board, and with first contact elements which are electrically conductively connected to the electronic circuit, wherein the first contact elements are designed to be welded to second contact elements of the electric motor, wherein the printed circuit board has through-openings for guiding through the second contact elements and for bringing the second contact elements into overlap with the first contact elements in respective welding portions, wherein at least one guide element for aligning the second contact elements with the through-openings and the welding portions is arranged in the interior of the housing on the side of the printed circuit board that is opposite to the first contact elements, wherein, on the side of the printed circuit board that faces the at least one guide element, the housing has a first opening for guiding the second contact elements into the housing and to the at least one guide element, and wherein at least one welding protection element for protecting the printed circuit board during welding of the contact elements is arranged in the interior of the housing.

Advantageous developments and example embodiments of the control device according to the present invention for controlling an electric motor are disclosed herein.

Particularly preferred is a structural example embodiment of the present invention in which the housing of the control device has a second opening, which can be closed by a cover element, in the region of the welding portions, through which second opening a welding device can be guided into the interior of the housing and to the welding portions. Such an embodiment makes possible, on the one hand, access or accessibility to the welding portions in a state in which the control device only needs to be closed with the cover element, and, on the other hand, a closed interior of the housing, which is thus in particular sealed against the ingress of media, after the second opening has been closed by means of the cover element.

For avoiding electrical short circuits as well as for simple assembly and adaptation of the guide element and/or of the welding protection element to the particular geometry of the control device or of the contact elements, it is preferably provided that the guide element and/or the welding protection element is designed as a plastic injection-molded part and connected to the housing via a corresponding latch connection.

The latch connection in particular makes it possible to fasten and position the guide element and/or the welding protection element easily without additional fasteners such as screws or similar fasteners.

A preferred geometry of the guide element provides that the guide element has a funnel-shaped catching region for a second contact element, the cross-section of said catching region decreasing toward the printed circuit board, and that, on the side that faces the printed circuit board, a guiding region having an at least substantially constant cross-section adjoins the catching region, the cross-section of said guiding region being adapted to the cross-section of the second contact element, wherein the cross-sections of the through-opening, assigned to a second contact element, in the printed circuit board and of the guiding region are aligned flush with each other in a direction perpendicular to the plane of the printed circuit board.

With regard to the geometry of the welding protection element, a preferred embodiment of the present invention provides that the welding protection element comprises a bottom portion with through-openings in the region of contact portions of the first contact elements with the printed circuit board, wherein the bottom portion is delimited by at least one side wall, which projects from the bottom portion toward a housing cover of the housing and is preferably arranged in abutting contact with the housing cover on an inner side of the housing upper part that faces the printed circuit board. Such a geometric design of the welding protection element makes it possible to protect the interior of the housing completely, since only the connection regions of the first contact elements with the printed circuit board are not overlapped or covered by the welding protection element in the region of the through-openings. Since the connection regions between the first contact elements and the printed circuit board are designed as electrically conductive connections, even weld spatters or the like impinging in the region of the first contact elements does not lead to damage to the electronic circuit or the components.

In addition, it is preferred that the first contact elements are contact springs designed as punched/bent parts. Such contact springs comprising a spring portion make it possible to connect the first contact elements particularly easily to the second contact elements since any geometric deviations that may occur in the connection region between the contact elements can be easily compensated by the spring portion.

Furthermore, the present invention comprises a drive unit consisting of a control device designed according to the present invention as described and an electric motor, wherein the electric motor comprises second contact elements, preferably in the form of plug pins, which are connected in welding portions to the first contact elements of the control device.

In a preferred development of a drive unit of the present invention, it is provided that the housing of the control device is connected in the region to a housing of the electric motor, and that the second contact elements are at least indirectly connected to winding wires of a stator of the electric motor.

The present invention also comprises a method for producing such a drive unit. According to an example embodiment of the present invention, the method comprising at least the following steps: First of all, the control device is produced. Then, the electric motor is connected to the housing of the control device by guiding the second contact elements through the first opening into the housing of the control device. Then, the second contact elements are guided through the at least one guide elements and the through-openings in the printed circuit board and the second contact elements are brought into alignment with the first contact elements in welding portions. Then, a rigid connection is preferably formed between the electric motor and the housing of the control device. Lastly, weld joints are formed between the first and the second contact elements.

A preferred development of the method of the present invention provides that, after the weld joints have been formed, the housing of the control device is closed in the region of a second opening of the control device by a cover element.

Further advantages, features, and details of the present invention become apparent from the following description of preferred embodiments of the present invention and from the figures.

### BRIEF DESCRIPTION OF THE DRAWINGS

FIG. 1 shows a longitudinal section through a control device for controlling an electric motor, according to an example embodiment of the present invention.

FIG. 2 shows a drive unit consisting of a control device according to FIG. 1 and an electric motor flanged to the control device, according to an example embodiment of the present invention.

FIG. 3 shows a detailed view of a connection region between contact elements of the control device and of the electric motor in an enlarged illustration, according to an example embodiment of the present invention.

### DETAILED DESCRIPTION OF EXAMPLE EMBODIMENTS

Identical elements or elements with the same function are provided with the same reference signs in the figures.

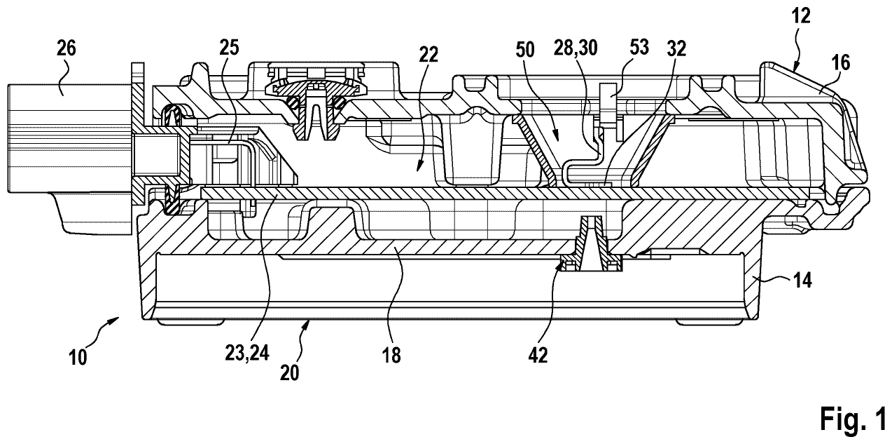

FIG. 1 shows a control device 10 which comprises a housing 12 designed in multiple parts. In the illustrated exemplary embodiment, the housing 12 comprises a housing lower part 14 and a substantially hood-like housing upper part 16 connected to the housing lower part 14. The housing lower part 14 and the housing upper part 16 are designed as die-cast aluminum parts by way of example. The housing lower part 14 comprises an intermediate bottom 18. On the side of the intermediate bottom 18 that faces away from the housing upper part 16, the housing lower part 14 furthermore has a first opening 20. An interior 22 is formed within the housing 12 between the housing upper part 16 and the intermediate bottom 18 of the housing lower part 14. The interior 22 serves to accommodate a circuit carrier 23 in the form of a printed circuit board 24. The printed circuit board 24 comprises an electronic circuit not shown in detail. The electronic circuit or the printed circuit board 24 is electrically contacted via plug pins 25, which are electrically conductively connected to the printed circuit board 24 on the one hand and, on the other hand, are guided outward via a plug connector body 26 in order to be electrically contacted by means of a corresponding mating plug. The plug connector body 26 is accommodated between the housing lower part 14 and the housing upper part 16.

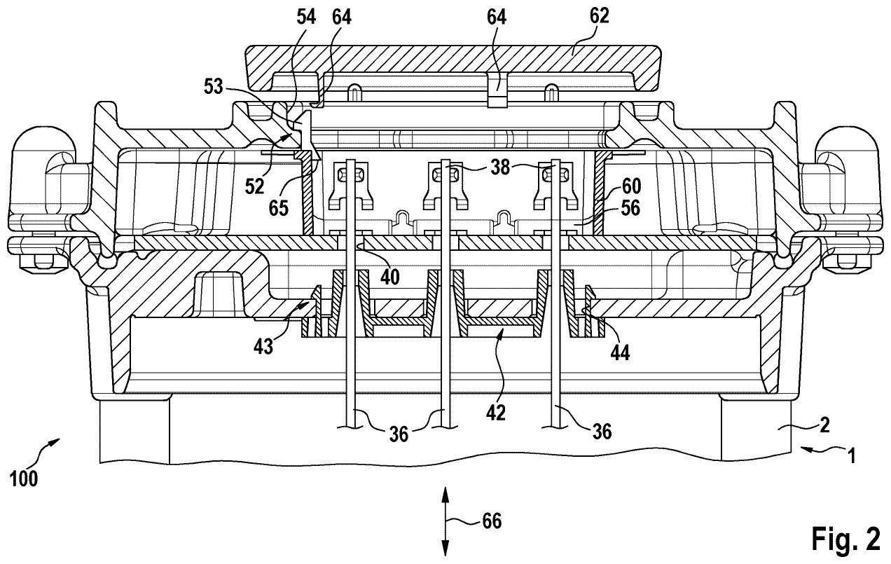

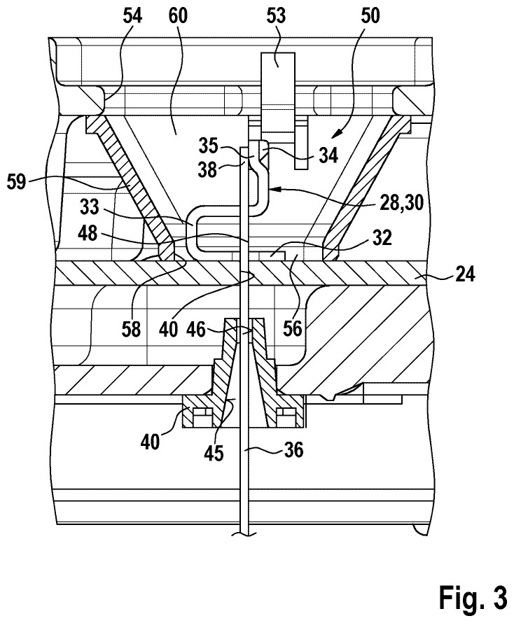

Multiple, in particular three, first contact elements 28 in the form of contact springs 30, which are designed as punched/bent parts, are arranged on the upper side of the printed circuit board 24 that faces away from the housing lower part 14. The contact springs 30 comprise a contact portion 32, which is arranged in parallel with the plane of the printed circuit board 24 and via which the contact springs 30 are electrically conductively contacted or connected to, for example, the electronic circuit of the printed circuit board 24 by soldered joints or the like. The contact portion 32 transitions into a U-shaped spring portion 33, which is in turn adjoined by at least one welding portion 34 with a bead-like elevation 35, the welding portion being used to connect each contact spring 30 to a corresponding second contact element 36 (visible in FIGS. 2 and 3) of an electric motor 1 in the form of a plug pin, namely by a (spot) weld joint between the elevation 35 on the welding portion 34 of the first contact element 28 and an end portion 38 of the second contact element 36. The welding portions 34 of the spring elements 30 are arranged in parallel with the end portions 38 of the second contact elements 36. The second contact element 36 is preferably designed as a punched part that has a rectangular cross-section and is made of sheet metal.

For guiding the second contact elements 36 through the printed circuit board 24, the printed circuit board 24 has a corresponding through-opening 40 for each second contact element 36. A guide element 42 for guiding, positioning and aligning the second contact elements 36 with the through-openings 40 in the printed circuit board 24 is arranged on the side of the through-openings 40 that faces the housing lower part 14. The guide element 42, which consists of plastic and is designed as an injection-molded part, can be latched by means of a first latch connection 43 in the region of an opening 44 formed in the intermediate bottom 18, in order to fasten the guide element 42 to the housing lower part 14.

On the side that faces away from the printed circuit board 24, the guide element 42 has a funnel-shaped catching region 45, which is adjoined in the direction toward the printed circuit board 24 by a guiding region 46 having an at least substantially constant cross-section. In the illustrated exemplary embodiment, the guiding region 46 ends at a distance from the underside of the printed circuit board 24, but it may, alternatively, also extend directly to the underside of the printed circuit board 24 or even be arranged in abutting contact with the underside of the printed circuit board 24.

It is essential that the cross-sections of both the guiding regions 46 and the through-openings 40 in the printed circuit board 24 are adapted to the cross-section of the second contact elements 36 in such a way that, at most, only a minor gap is formed between the cross-section of the second contact elements 36 and the cross-sections of the guiding regions 46 or of the through-openings 40. In addition, the guiding regions 46 of the guide element 42 are aligned flush with the through-openings 40 in the printed circuit board 24 in a direction perpendicular to the plane of the printed circuit board 24. The contact portion 32 of each contact spring 30 furthermore has an aperture 48 in the region of the through-opening 40 of the printed circuit board 24 so that the second contact elements 36 pass through the contact portions 32 of the contact springs 30.

In addition, a welding protection element 50 is arranged on the side of the printed circuit board 24 that faces away from the housing lower part 14. The welding protection element 50 is connected to the housing upper part 16 in the region of a second opening 54 of the housing upper part 16 via a second latch connection 52 with multiple latching hooks 53. The welding protection element 50, which consists of plastic and is designed as an injection-molded part, comprises a bottom portion 56 with through-openings 58 in the region of the contact portions 32 of the contact springs 30. Furthermore, the bottom portion 56 is delimited by at least one side wall 59, 60, which is arranged perpendicularly or at an oblique angle to the plane of the printed circuit board 24, projects to the height of the underside of the second opening 54 and is preferably arranged in abutting contact with the underside of the inner wall of the housing upper part 16 that faces the printed circuit board 24.

In addition, it is essential that the welding protection element 50, which protects the interior 22 of the control device 10 from weld spatters or the like when forming weld joints between the contact elements 28 and 36, makes possible, on the side that faces the second opening 54, accessibility to the welding portions 34 and the second contact elements 36 by a welding tool (not shown) via the second opening 54.

The second opening 54 of the housing upper part 16 can be closed by means of a cover element 62, which is preferably designed as a plastic injection-molded part. To this end, the cover element 62 comprises additional latching hooks 64, which cooperate, for example, with undersides 65 on the latching hooks 53 of the welding protection element 50.

The second contact elements 36 form so-called upright wires and are electrically conductively connected (not shown) at least indirectly to winding wires of a stator of the electric motor 1, which form three electrical phases of the electric motor 1 by way of example. The electric motor 1 together with the control device 10 forms a drive unit 100, wherein the electric motor 1 comprises a housing 2 (shown only schematically in FIG. 2), via which the housing 12 of the control device 10 is connected to the electric motor 1, for example by means of screw connections not shown.

The drive unit 100 is formed by first of all manufacturing or producing the control device 10 in a first step, in particular by also connecting the guide element 42 and the welding protection element 50 to the housing 12 in the manner described. It is essential that, initially, the second opening 54 on the housing upper part 16 is not yet closed by means of the cover element 62. Then, in a second step, the electric motor 1 and the control device 10 are moved toward each other and joined. To this end, the second contact elements 36 are guided via the first opening 20 into the catching regions 45 of the guide element 42 in the joining direction 66 shown in FIGS. 2 and 3, which is perpendicular to the plane of the printed circuit board 24 or parallel to the second contact elements 36. Via the guiding regions 46 of the guide element 42, the second contact elements 36 are then guided through the through-openings 40 of the printed circuit board 24 and into the region or into overlap with the welding portions 34 of the first contact elements 28. When this position of the second contact elements 36 is reached, the housing 2 of the electric motor 1 is preferably connected to the housing 12 of the control device 10, for example by means of the mentioned screw connections (not shown). Then, via the second opening 54 in the housing upper part 16, a welding device is guided into the interior 22 of the housing 12, namely in such a way that the welding device is located within or surrounded by the welding protection element 50. The mentioned welding device (not shown) is then used to form the weld joints between the contact elements 28 and 36. Lastly, after the welding device has been moved out of the housing 12 of the control device 10, the second opening 54 is closed by means of the cover element 62.

The control device 10 described thus far or the drive unit 100 can be altered or modified in many ways without deviating from the idea of the present invention.

1-10. (canceled)

11. A control device for controlling an electric motor, comprising:
a housing having an interior and in which a circuit carrier which includes an electronic circuit is arranged in the form of a printed circuit board;
first contact elements, which are electrically conductively connected to the electronic circuit, wherein the first contact elements are configured to be welded to second contact elements of the electric motor;
wherein the printed circuit board has through-openings for guiding through the second contact elements and for bringing the second contact elements into overlap with the first contact elements in respective welding portions, wherein at least one guide element for aligning the second contact elements with the through-openings and the welding portions is arranged in the interior of the housing on the side of the printed circuit board that is opposite to the first contact elements, wherein, on a side of the printed circuit board that faces the at least one guide element, the housing has a first opening for guiding the second contact elements into the housing and to the at least one guide element, and wherein at least one welding protection element configured to protect the printed circuit board during welding of the contact elements is arranged in the interior of the housing.

12. The control device according to claim 11, wherein, in a region of the welding portions, the housing has a second opening, which can be closed by a cover element and via which a welding device can be guided into the interior of the housing and to the welding portions.

13. The control device according to claim 11, wherein the at least one guide element and/or the at least one welding protection element are configured as a plastic injection-molded part and are connected to the housing via a corresponding latch connection.

14. The control device according to claim 11, wherein the at least one guide element has a funnel-shaped catching region for a second contact element, a cross-section of the catching region decreasing toward the printed circuit board, and on a side that faces the printed circuit board, a guiding region having an at least substantially constant cross-section adjoins the catching region, a cross-section of the guiding region being adapted to a cross-section of the second contact element, wherein cross-sections of the through-opening, assigned to a second contact element, in the printed circuit board and of the guiding region are aligned flush with each other in a direction perpendicular to a plane of the printed circuit board.

15. The control device according to claim 11, wherein the at least one welding protection element includes a bottom portion with through-openings in a region of contact portions of the first contact elements with the printed circuit board, wherein the bottom portion is delimited by at least one side wall, which projects from the bottom portion toward a housing upper part of the housing and is arranged in abutting contact with the housing upper part on an inner side of the housing upper part that faces the printed circuit board.

16. The control device according to claim 11, wherein the first contact elements are contact springs configured as punched/bent parts.

17. A drive unit comprising:
a control device, including:
a housing having an interior and in which a circuit carrier which includes an electronic circuit is arranged in the form of a printed circuit board,
first contact elements, which are electrically conductively connected to the electronic circuit, wherein the first contact elements are configured to be welded to second contact elements of an electric motor,
wherein the printed circuit board has through-openings for guiding through the second contact elements and for bringing the second contact elements into overlap with the first contact elements in respective welding portions, wherein at least one guide element for aligning the second contact elements with the through-openings and the welding portions is arranged in the interior of the housing on the side of the printed circuit board that is opposite to the first contact elements, wherein, on a side of the printed circuit board that faces the at least one guide element, the housing has a first opening for guiding the second contact elements into the housing and to the at least one guide element, and wherein at least one welding protection element configured to protect the printed circuit board during welding of the contact elements is arranged in the interior of the housing; and
the electric motor including the second contact elements connected to the first contact elements in a region of welding portions.

18. The drive unit according to claim 17, wherein the housing of the control device is connected to a housing of the electric motor, and the second contact elements are at least indirectly connected to winding wires of a stator of the electric motor.

19. A method for producing a drive unit, the drive using including:
a control device, including:
a housing having an interior and in which a circuit carrier which includes an electronic circuit is arranged in the form of a printed circuit board,
first contact elements, which are electrically conductively connected to the electronic circuit, wherein the first contact elements are configured to be welded to second contact elements of an electric motor,
wherein the printed circuit board has through-openings for guiding through the second contact elements and for bringing the second contact elements into overlap with the first contact elements in respective welding portions, wherein at least one guide element for aligning the second contact elements with the through-openings and the welding portions is arranged in the interior of the housing on the side of the printed circuit board that is opposite to the first contact elements, wherein, on a side of the printed circuit board that faces the at least one guide element, the housing has a first opening for guiding the second contact elements into the housing and to the at least one guide element, and wherein at least one welding protection element configured to protect the printed circuit board during welding of the contact elements is arranged in the interior of the housing; and
the electric motor including the second contact elements connected to the first contact elements in a region of welding portions;
the method comprising at least the following steps:
producing the control device;
connecting the electric motor to the housing of the control device, including guiding the second contact elements through the first opening into the housing;
guiding the second contact elements through the at least one guide element and the through-openings in the printed circuit board and bringing the second contact elements into alignment with the first contact elements in the region of welding portions;
forming a rigid connection between the electric and the housing of the control device; and
forming weld joints between the first and the second contact elements.

20. The method according to claim 19, wherein after the weld joints have been formed, the housing is closed in a region of a second opening by a cover element.
